(19) United States
(12) Patent Application Publication
(10) Pub. No.: US 2026/0082593 A1
(43) Pub. Date: Mar. 19, 2026

(54) SEMICONDUCTOR STRUCTURE AND FORMING METHOD THEREOF

(71) Applicant: NANYA TECHNOLOGY CORPORATION, New Taipei City (TW)

(72) Inventor: Chen Chang LI, New Taipei City (TW)

(21) Appl. No.: 19/328,256

(22) Filed: Sep. 15, 2025

(30) Foreign Application Priority Data
Sep. 16, 2024 (TW) 113135148

(51) Int. Cl. H10D 1/00; H10D 1/68

(52) U.S. Cl. CPC H10D 1/042; H10D 1/714; H10D 1/716

(57) ABSTRACT

A semiconductor structure includes a substrate and a capacitor structure. The substrate includes a semiconductor substrate, a dielectric layer disposed on the semiconductor substrate, and a plurality of metal contacts disposed in the dielectric layer. The capacitor structure includes a plurality of vertical capacitor cups coupled to the metal contacts, respectively. Each of the vertical capacitor cups has an inside height and an outside height, in which the inside height is smaller than the outside height. A method of forming the semiconductor structure is also disclosed.

### CROSS-REFERENCE TO RELATED APPLICATION

This application claims priority to Taiwan Application Serial Number 113135148, filed Sep. 16, 2024, which is herein incorporated by reference in its entirety.

### BACKGROUND

### Field of Invention

The present disclosure relates to a semiconductor structure and forming method thereof.

### Description of Related Art

Dynamic random access memory (DRAM) components are widely used in semiconductor electronic devices. With the thin, light, small, and short developments of electronic devices, the design of the DRAM components requires higher density to meet the developments of electronic devices.

Capacitors are popular components being utilized in integrated circuit and can be served as charge storage element of DRAM. In order to reduce the volume of the capacitors, the trend of designing the capacitors is a tall and thin pillar capacitor, to increase surface area of the capacitors. However, the pillar capacitor with high aspect etching ratio is really difficult to fabricate. Therefore, there is a need to form a pillar capacitor by a reliable method.

### SUMMARY

An aspect of the disclosure provides a method of forming semiconductor structure. The method includes forming a template layer on a substrate, wherein the template layer sequentially comprises, from bottom to top, a first support layer, a first sacrificial layer, a second support layer, a second sacrificial layer, a third support layer, a third sacrificial layer, and a fourth support layer, wherein the second support layer comprises a first opening, the third support layer comprises a second opening, and the second opening substantially corresponds to the first opening; forming a plurality of through holes penetrating the template layer to expose the substrate, wherein the through holes partially overlap the first opening and the second opening; forming a first conductive layer on sidewalls of the through holes and on a top surface of the fourth support layer; removing a first portion of the first conductive layer and a portion of the fourth support layer in a vertical projection area of the first opening and the second opening to expose the third sacrificial layer; removing a second portion of the first conductive layer on the fourth support layer; removing the first sacrificial layer, the second sacrificial layer, and the third sacrificial layer; and sequentially forming a capacitor dielectric layer and a second conductive layer on the first conductive layer to form a container.

Another aspect of the disclosure provides a semiconductor structure including a substrate and a container. The substrate includes a semiconductor substrate, a dielectric layer disposed on the semiconductor substrate, and a plurality of metal contacts disposed in the dielectric layer. The container includes a plurality of vertical capacitor cups connected to the metal contacts, respectively, wherein each of the vertical capacitor cups has an inner height and an outer height, and the inner height is smaller than the outer height.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIGS. 1A, 2A, 3A, 4, 5A, 6, 7, and 8A are cross-sectional side views of different stages of the method of forming semiconductor structure according to some embodiments of the disclosure.

FIGS. 1B, 2B, 3B, and 8C are cross-sectional top views taken along plane A-A in FIGS. 1A, 2A, 3A, and 8C.

FIGS. 5B and 8B are cross-sectional top views taken along plane B-B in FIGS. 5A and 8A.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following illustrations include exemplary operations, but the operations are not necessarily performed in the order shown. Operations may be added, replaced, changed order, and/or eliminated as appropriate, in accordance with the spirit and scope of various embodiments of the present disclosure.

In order to form tall and thin pillar containers, an example process includes following steps. A template layer including alternately arranged support layers and sacrificial layers is formed. The template layer is etched to form a plurality of through holes. A conductive layer is filled in the through holes to form containers. Multiple hole-opening processes are performed to the support layers and multiple etching processes are performed to remove the sacrificial layers of the containers. A polysilicon layer is then filled in the containers. The containers including two conductive layers and a dielectric layer therebetween are formed.

However, the multiple hole-opening processes may cause damage at the top of the containers, which leads to area loss at the vertical direction of the containers, thus the capacitance of the containers is reduced. Additionally, multiple etching processes of removing sacrificial layers may also cause loss of the support layers, and the structural strength is reduced, and the containers may be easily tilted thereby causing leakage.

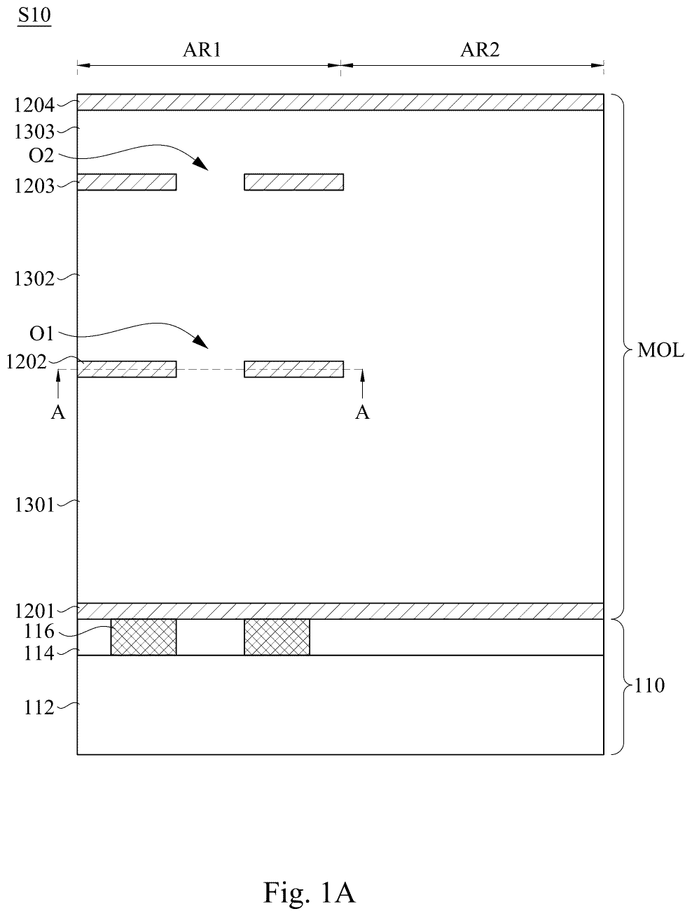

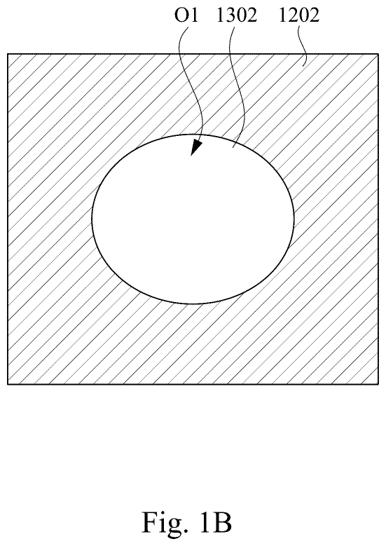

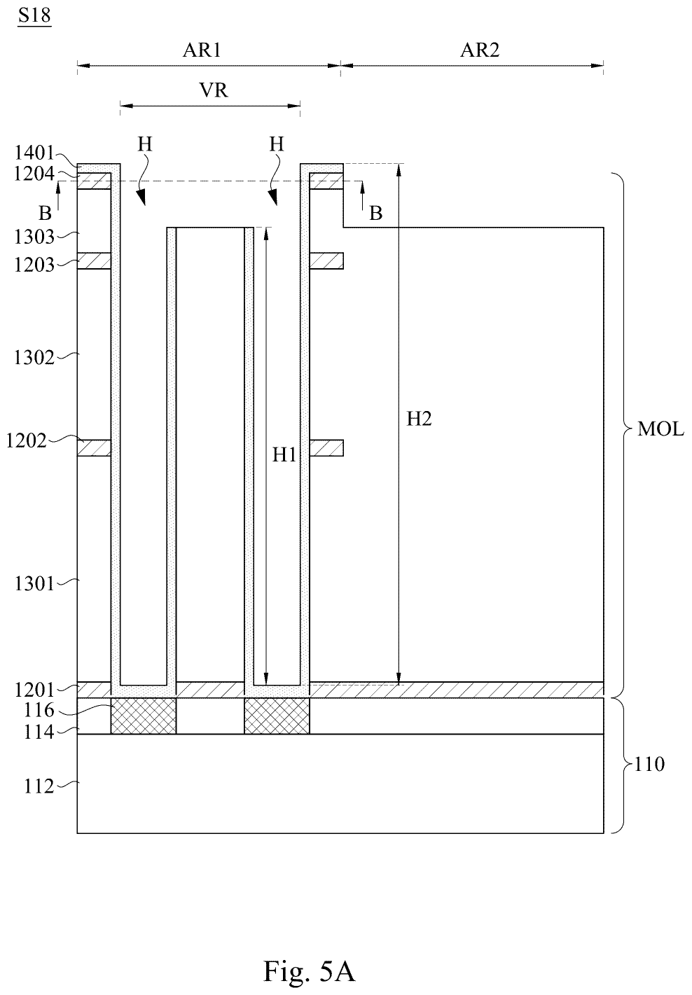

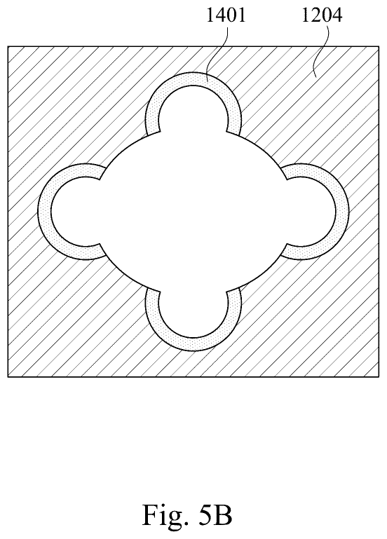

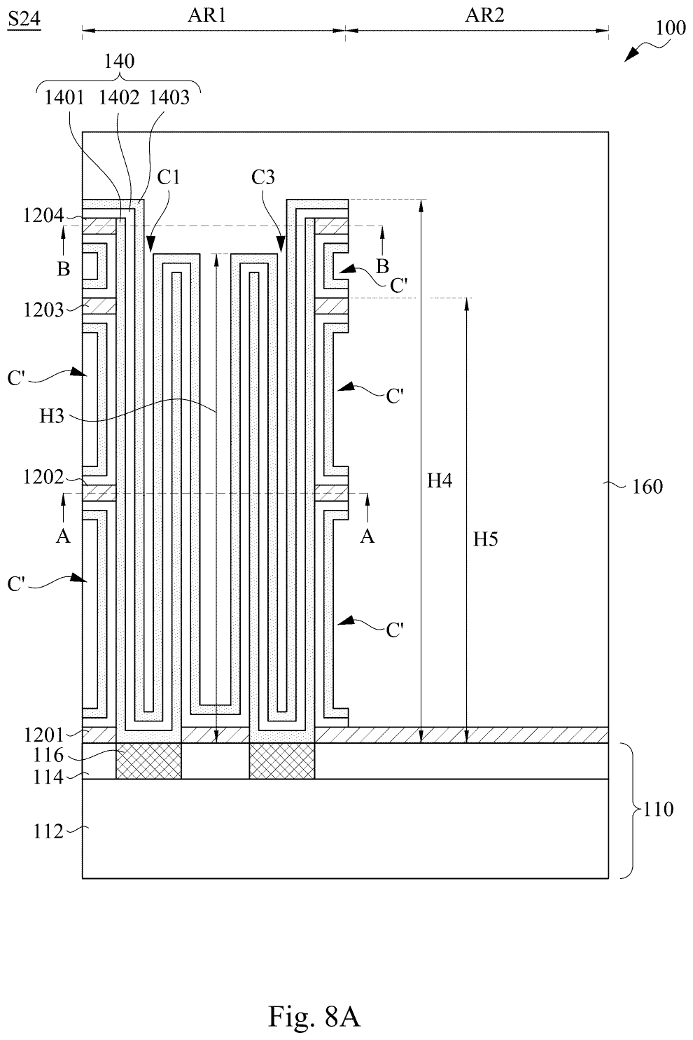

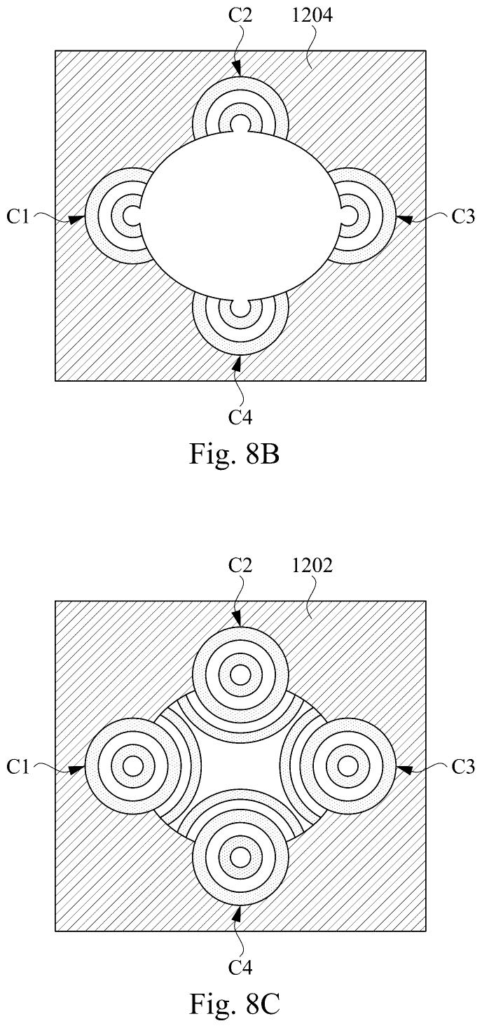

As a result, the present disclosure provides a method of forming semiconductor structure, as shown in FIG. 1A to FIG. 8C, which are cross-sectional top views and cross-sectional side views of different stages of the method of forming semiconductor structure according to some embodiments of the disclosure. FIGS. 1A, 2A, 3A, 4, 5A, 6, 7, and 8A are cross-sectional side views of different stages of the method of forming semiconductor structure according to some embodiments of the disclosure. FIGS. 1B, 2B, 3B, and 8C are cross-sectional top views taken along plane A-A in FIGS. 1A, 2A, 3A, and 8C. FIGS. 5B and 8B are cross-sectional top views taken along plane B-B in FIGS. 5A and 8A.

Reference is made to FIGS. 1A and 1B. The method of forming the semiconductor structure begins at step S10. Step S10 includes forming a template layer MOL on a substrate 110. The template layer MOL sequentially includes, from bottom to top, a first support layer 1201, a first sacrificial layer 1301, a second support layer 1202, a second sacrificial layer 1302, a third support layer 1203, a third sacrificial layer 1303, and a fourth support layer 1204. The second support layer 1202 includes a first opening O1. The third support layer 1203 includes a second opening O2. The second opening O2 substantially corresponds to the first opening O1.

The step S10 further includes following sub-steps: sequentially forming the first support layer 1201, the first sacrificial layer 1301, and the second support layer 1202 on the substrate 110. The first opening O1 is formed penetrating the second support layer 1202 to expose the first sacrificial layer 1301. The second sacrificial layer 1302 and the third support layer 1203 are sequentially formed on the second support layer 1202, in which the first opening O1 is filled by the second sacrificial layer 1302. The second opening O2 is formed penetrating the third support layer 1203 to expose the second sacrificial layer 1302. The third sacrificial layer 1303 and the fourth support layer 1204 are sequentially formed on the third support layer 1203, in which the second opening O2 is filled by the third sacrificial layer 1303.

In some embodiments, the coverage area of the first support layer 1201 and the fourth support layer 1204 is greater than the coverage area of the second support layer 1202 and the third support layer 1203. For example, the template layer MOL includes a capacitor array area AR1 and a preserved area AR2. The first opening O1 and the second opening O2 are formed in the capacitor array area AR1. The second support layer 1202 and the third support layer 1203 do not extend into the preserved area AR2. Namely, portion of the second support layer 1202 is removed simultaneously when the first opening O1 is formed, and portion of the third support layer 1203 is removed simultaneously when the second opening O2 is formed. The first support layer 1201 and the fourth support layer 1204 are continuously extended from the capacitor array area AR1 to the preserved area AR2. The first sacrificial layer 1301, the second sacrificial layer 1302, and the third sacrificial layer 1303 are continuously between the first support layer 1201 and the fourth support layer 1204 at the preserved area AR2, and the first sacrificial layer 1301, the second sacrificial layer 1302, and the third sacrificial layer 1303 are separated by the second support layer 1202 and the third support layer 1203 at the capacitor array area AR1. In some embodiments, the preserved area AR2 can be slots or through holes.

In some embodiments, the material of each of the first support layer 1201, the second support layer 1202, the third support layer 1203, and the fourth support layer 1204 includes insulating nitride material, such as silicon nitride (Si₃N₄), but the present disclosure is not limited to. The material of the support layers has higher rigidity, and the support layers serve as frames or grids of the array structure and surround the sequentially formed containers to prevent the containers from being damaged or collapsed.

The material of each of the first sacrificial layer 1301, the second sacrificial layer 1302, and the third sacrificial layer 1303 includes insulating oxide material such as silicon oxide (SiO₂), silicon oxynitride, or combinations thereof, but the present disclosure is not limited to. The sacrificial layers serve as filling or mold of the array structure and would be removed after the containers are formed.

In some embodiments, the first support layer 1201, the first sacrificial layer 1301, the second support layer 1202, the second sacrificial layer 1302, the third support layer 1203, the third sacrificial layer 1303, and the fourth support layer 1204 are respectively formed by atomic layer deposition process, chemical vapor deposition process, physical deposition process, e-beam vapor deposition process, and/or other possible process.

In some embodiments, the first opening O1 and the second opening O2 are respectively formed by dry etching process, wet etching process, reactive ion etching process, and/or other possible process. The etching process can be performed by using a patterned photoresist (not shown) as a mask. In some embodiments, a diameter of the first opening O1 is substantially equal to a diameter of the second opening O2.

In some embodiments, the substrate 110 includes a semiconductor substrate 112. The material of the semiconductor substrate 112 may include Si, Ge, SiGe, III-V semiconductor material, or combinations thereof, but the present disclosure is not limited to. In some embodiments, the semiconductor substrate 112 includes an active region and an isolation region (not shown). The substrate 110 further includes a dielectric layer 114 on the top surface of the semiconductor substrate 112 and a plurality of metal contacts 116 disposed in the dielectric layer 114. The metal contacts 116 are arranged along a horizontal direction. The metal contacts 116 are electrically connected to the active region of the semiconductor substrate 112 and are coupled to the sequentially formed containers. In some other embodiments, the semiconductor structure may include additional components.

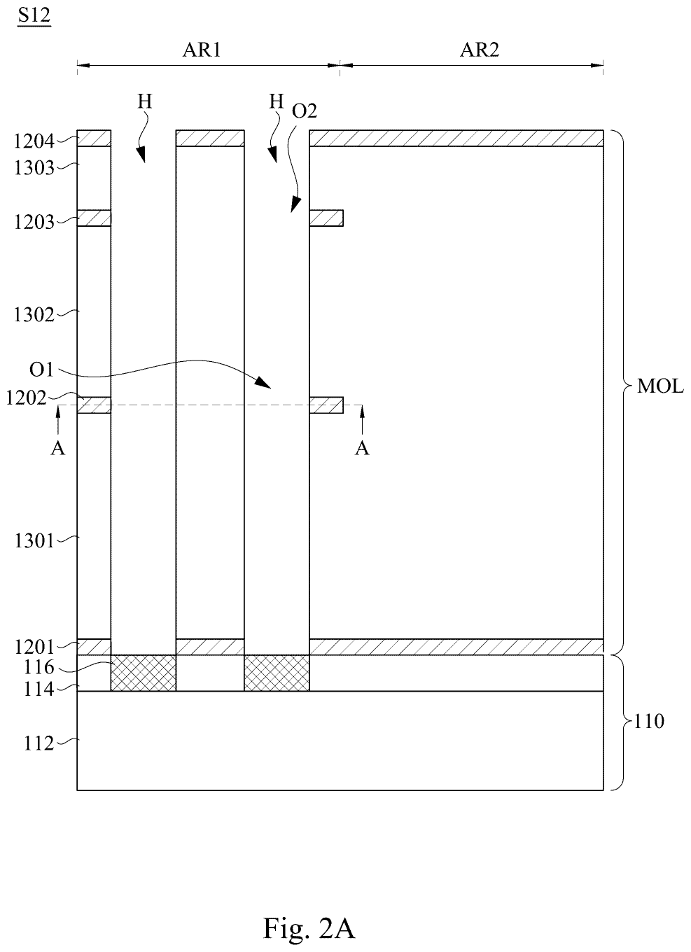

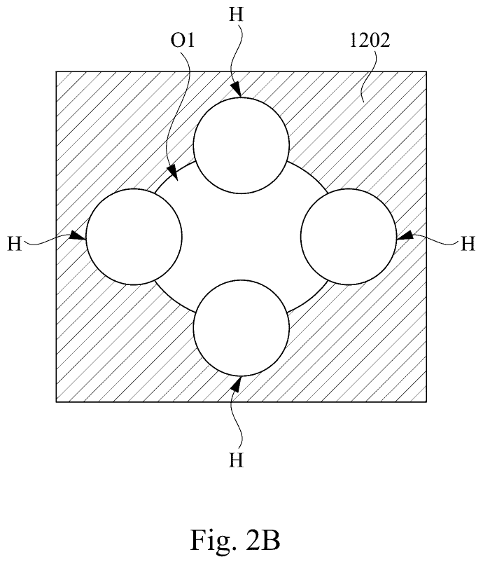

Reference is made to FIG. 2A and FIG. 2B. The method of forming the semiconductor structure goes to step S12, in which a plurality of through holes H are formed penetrating the template layer MOL to expose the metal contacts 116 of the substrate 110. The through holes H are formed partially overlapping the first opening O1 in the second support layer 1202 and the second opening O2 in the third support layer 1203. In some embodiments, the through holes H are formed by dry etching process, wet etching process, reactive ion etching process, and/or other possible process. The etching process can be performed by using a patterned photoresist (not shown) as a mask.

In some embodiments, the shape of each of the first opening O1 in the second support layer 1202 and the second opening O2 in the third support layer 1203 can be an ovular or an ellipse, to meet best density arrangement. The number of the through holes H is four, and the four through holes H are arranged at long-axis and short axis of the first opening O1 in the second support layer 1202 and the second opening O2 in the third support layer 1203.

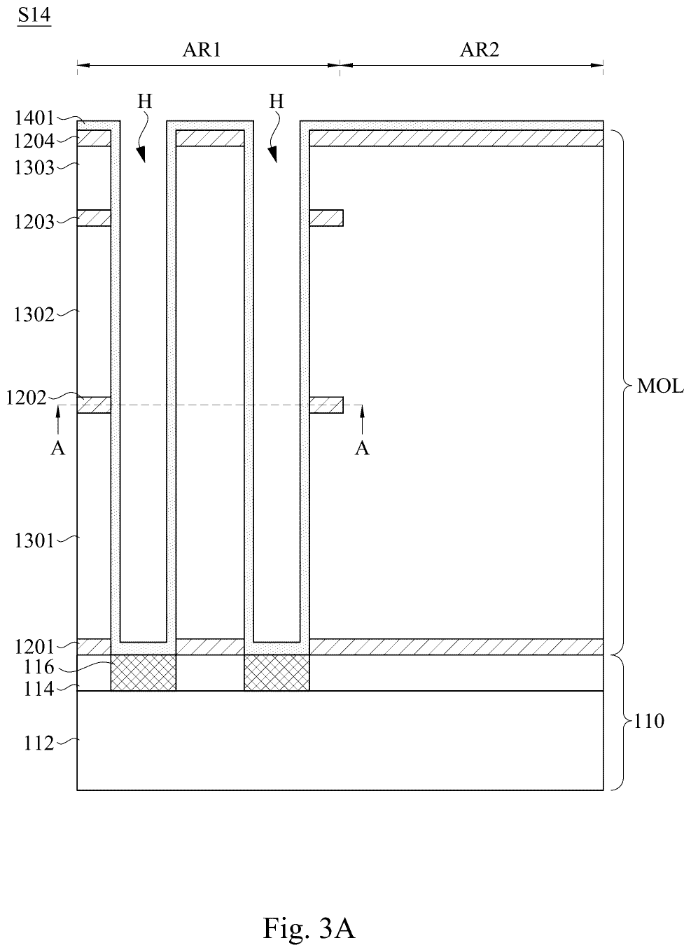

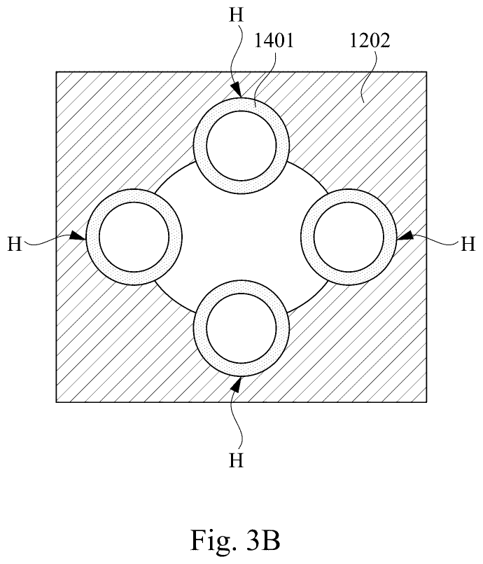

Reference is made to FIG. 3A and FIG. 3B. The method of forming the semiconductor structure goes to step S14, in which a first conductive layer 1401 is formed in the through holes H. In some embodiments, the first conductive layer 1401 is conformally formed on the sidewalls and the bottom surfaces of the through holes H, and the first conductive layer 1401 is further connected to the metal contacts 116 in the substrate 110. In some embodiments, the first conductive layer 1401 is in contact with the top surfaces of the metal contacts 116, the first conductive layer 1401 is in contact with the side surfaces of the first support layer 1201, the first sacrificial layer 1301, the second support layer 1202, the second sacrificial layer 1302, the third support layer 1203, the third sacrificial layer 1303, and the fourth support layer 1204, and the first conductive layer 1401 is in contact with the top surface of the fourth support layer 1204. Namely, in the capacitor array area AR1, the first support layer 1201, the second support layer 1202, the third support layer 1203, and the fourth support layer 1204 are connected to the vertical portions of the first conductive layer 1401 along the through holes H.

In some embodiments, the material of the first conductive layer 1401 includes conductive material. The conductive material includes metal, metal alloy, metal nitride, metal silicide, or combinations thereof. The present disclosure is not limited to. The first conductive layer 1401 can be formed by atomic layer deposition process, chemical vapor deposition process, physical deposition process, e-beam vapor deposition process, and/or other possible process.

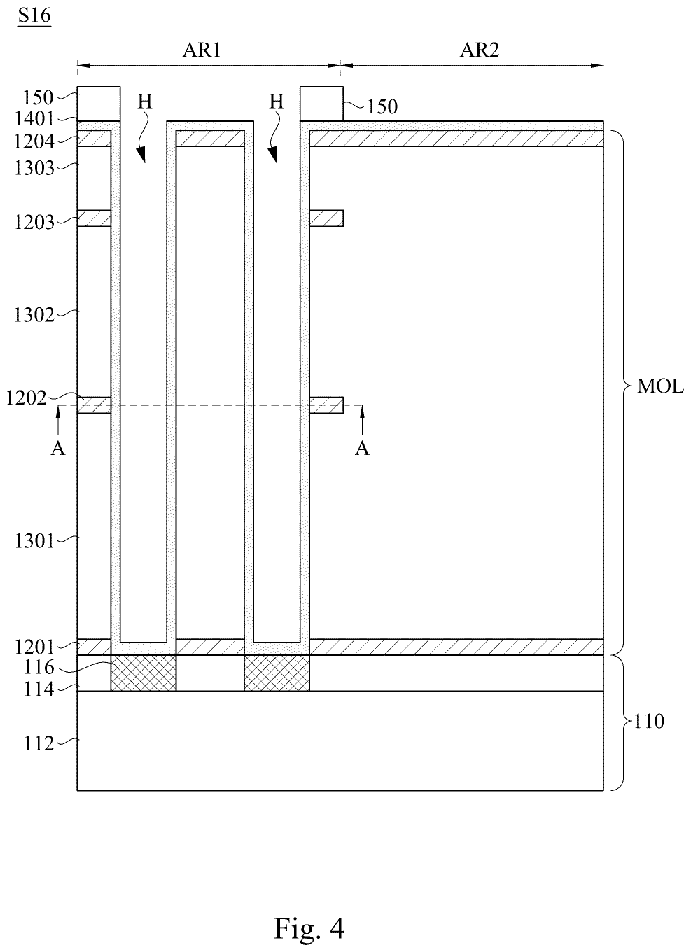

Reference is made to FIG. 4. The method of forming the semiconductor structure goes to step S16, in which a patterned photoresist 150 is formed on the capacitor array area AR1, in which the patterned photoresist 150 covers the area other than the first opening O1 and the second opening O2 (see FIG. 1A and FIG. 1B), and the patterned photoresist 150 is not disposed on the preserved region AR2. Namely, the patterned photoresist 150, the second support layer 1202, and the third support layer 1203 have same distributing pattern. The top surface of the fourth support layer 1204 located in the first opening O1 and the second opening O2 is also free of being disposed with the patterned photoresist 150.

Reference is made to FIG. 5A and FIG. 5B. The method of forming the semiconductor structure goes to step S18, in which an etching process is performed using the patterned photoresist 150 (see FIG. 4) as a mask, to remove portions of the fourth support layer 1204 and the first conductive layer 1401 that are not protected by the patterned photoresist 150. For example, the portions of the fourth support layer 1204 and the first conductive layer 1401 that are located in a vertical projection area VR of the first opening O1 and the second opening O2 are removed, and the portions of the fourth support layer 1204 and the first conductive layer 1401 that are located in the preserved area AR2 are also removed. In some embodiments, the portion of the third sacrificial layer 1303 uncovered by the patterned photoresist 150 is also removed after the etching process. Then the patterned photoresist 150 is removed.

Because the portions of the third sacrificial layer 1303, the fourth support layer 1204, and the first conductive layer 1401 within the vertical projection area VR of the first opening O1 and the second opening O2 are removed, the height H1 of the portion of the first conductive layer 1401 within the vertical projection area VR of the first opening O1 and the second opening O2 is shorter than the height H2 of the portion of the first conductive layer 1401 protected by the patterned photoresist 150, thus the shape of the first conductive layer 1401 observed at the plane B-B is not a complete ring.

Additionally, after the etching process is performed, the top surface of the third sacrificial layer 1303 within the vertical projection area VR of the first opening O1 and the second opening O2 is exposed, and the top surface of the third sacrificial layer 1303 in the preserved area AR2 is also exposed. The side surfaces of the first sacrificial layer 1301, the second sacrificial layer 1302, and the third sacrificial layer 1303 are covered by the first conductive layer 1401 at the capacitor array region AR1. A height of the third sacrificial layer 1303 within the vertical projection area VR of the first opening O1 and the second opening O2 is between the third support layer 1203 and the fourth support layer 1204.

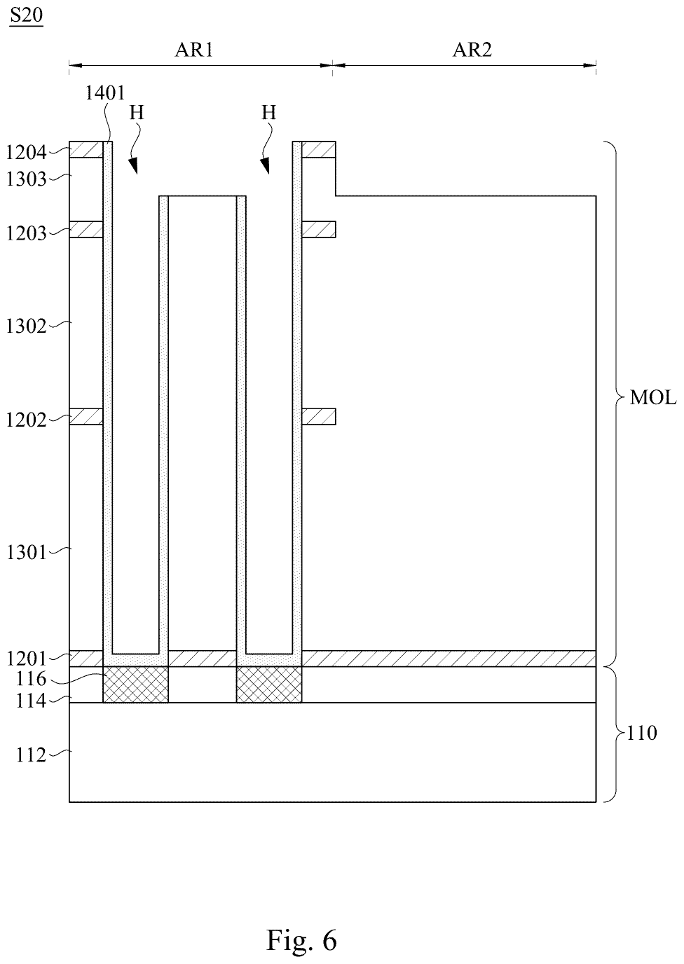

Reference is made to FIG. 6. The method of forming the semiconductor structure goes to step S20, including removing the remaining first conductive layer 1401 on the top surface of the fourth support layer 1204. The portion of the fourth support layer 1204 at the capacitor array region AR1 is still remained after step S20. Namely, in the capacitor array area AR1, the first support layer 1201, the second support layer 1202, the third support layer 1203, and the fourth support layer 1204 are connected to the vertical portions of the first conductive layer 1401 along the through holes H.

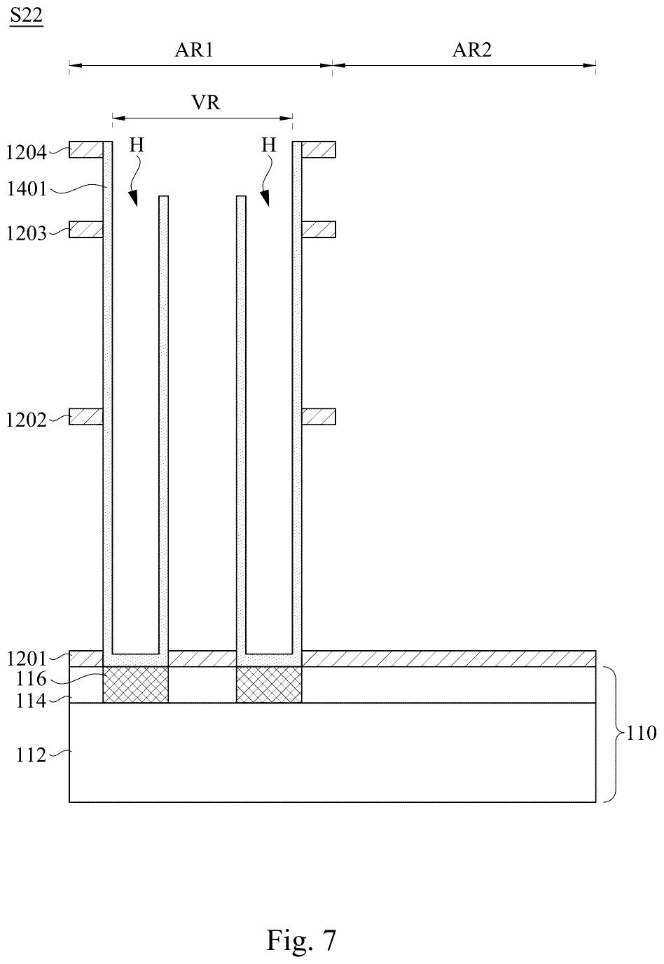

Reference is made to FIG. 7. The method of forming the semiconductor structure goes to step S22, in which the first sacrificial layer 1301, the second sacrificial layer 1302, and the third sacrificial layer 1303 (see FIG. 6) are removed by a wet etching process. More particularly, because the first opening O1 and the second opening O2 (see FIG. 1A and FIG. 1B) are formed in the second support layer 1202 and the third support layer 1203 at the capacitor array area AR1, in the step of S18 as shown in FIG. 5A and FIG. 5B, only the portions of the fourth support layer 1204 and the first conductive layer 1401 within the vertical projection of the first opening O1 and the second opening O2 are removed, and the underlying sacrificial layer material (including the continuous first sacrificial layer 1301, the second sacrificial layer 1302, and the third sacrificial layer 1303) can be exposed. Thus the loss of the first conductive layer 1401 can be reduced.

Additionally, the second support layer 1202 and the third support layer 1203 at the preserved area AR2 are also removed in advance, therefore, in the step of S18 as shown in FIG. 5A and FIG. 5B, only the portions of the fourth support layer 1204 and the first conductive layer 1401 within the preserved area AR2 are removed, and the underlying sacrificial layer material (including the continuous first sacrificial layer 1301, the second sacrificial layer 1302, and the third sacrificial layer 1303) can be exposed. Therefore, the first sacrificial layer 1301, the second sacrificial layer 1302, and the third sacrificial layer 1303 can be removed simultaneously by performing a single wet etching process. Thus the situation of damaging the third support layer 1203, the second support layer 1202, and the first conductive layer 1401 due to using multiple etching processes to remove the third sacrificial layer 1303, the third support layer 1203, the second sacrificial layer 1302, the second support layer 1202, and the first sacrificial layer 1301 can be prevented.

The loss at top of the first conductive layer 1401 is reduced, thus the sequentially formed containers may have greater area in the vertical direction, thereby increasing capacitance. Furthermore, by reducing the loss of the second support layer 1202 and the third support layer 1203, the mechanical strength of the array structure can be enhanced, and the problem of leakage due to container inclined can be prevented.

Finally, reference is made to FIG. 8A, FIG. 8B, and FIG. 8C. The method of forming the semiconductor structure goes to step S24, in which a capacitor dielectric layer 1402 is formed on the first conductive layer 1401, the first support layer 1201, the second support layer 1202, the third support layer 1203, and the fourth support layer 1204 at the capacitor array area AR1, and then a second conductive layer 1403 is formed on the first conductive layer 1401 at the capacitor array area AR1. The capacitor dielectric layer 1402 is sandwiched between the first conductive layer 1401 and the second conductive layer 1403 such that the semiconductor structure 100 including container 140 is provided. The step S24 further includes depositing polysilicon material 160 in the spacing in the container 140 and in the spacing between the first support layer 1201, the second support layer 1202, the third support layer 1203, and the fourth support layer 1204. The polysilicon material 160 covers the container 140.

In some embodiments, the material of the capacitor dielectric layer 1402 includes dielectric material. In some embodiments, the material of the capacitor dielectric layer 1402 includes high-k dielectric material. The capacitor dielectric layer 1402 can be formed by atomic layer deposition process, chemical vapor deposition process, physical deposition process, e-beam vapor deposition process, and/or other possible process.

In some embodiments, the material of the second conductive layer 1403 includes conductive material. The conductive material includes metal, metal alloy, metal nitride, metal silicide, or combinations thereof. The present disclosure is not limited to. The second conductive layer 1403 can be formed by atomic layer deposition process, chemical vapor deposition process, physical deposition process, e-beam vapor deposition process, and/or other possible process.

In step S24, the first conductive layer 1401, the second conductive layer 1403, and the capacitor dielectric layer 1402 therebetween construct a plurality of vertical capacitor cups C1-C4. The vertical capacitor cups C1-C4 corresponds to the through holes H (see FIG. 3B). Each of the vertical capacitor cups C1-C4 is connected to the corresponding metal contact 116. Each of the vertical capacitor cups C1-C4 has an inner height H3 and an outer height H4, in which the outer height H4 is measured at a side surface of each of the vertical capacitor cups C1-C4 that contacts the second support layer 1202, the third support layer 1203, and the fourth support layer 1204, and the inner height H3 is measured at a side surface of each of the vertical capacitor cups C1-C4 that is not adjacent the second support layer 1202, the third support layer 1203, and the fourth support layer 1204. The inner height H3 of each of the vertical capacitor cups C1-C4 is smaller than the outer height H4, and the inner height H3 of each of the vertical capacitor cups C1-C4 is higher than a height H5 of the third support layer 1203.

At the upper section of the container 140, as shown in the plane of FIG. 8B, the top cross-sectional view of each of the vertical capacitor cups C1-C4 is not a complete ring, in which the inner portion of each of the vertical capacitor cups C1-C4 is removed. On the other hand, at the middle and bottom section of the container 140, as shown in the plane of FIG. 8C, the top cross-sectional view of each of the vertical capacitor cups C1-C4 is a complete ring.

In some embodiments, the first conductive layer 1401, the capacitor dielectric layer 1402, and the second conductive layer 1403 among the vertical capacitor cups C1-C4 can be connected. In some embodiments, the first conductive layer 1401, the capacitor dielectric layer 1402, and the second conductive layer 1403 among different vertical capacitor cups C1-C4 can be separated.

In some embodiments, the capacitor dielectric layer 1402 and the second conductive layer 1403 not only form on sidewalls of the first conductive layer 1401, but also form on surfaces of the first support layer 1201, the second support layer 1202, the third support layer 1203, and the fourth support layer 1204. The laterally arranged first conductive layer 1401, capacitor dielectric layer 1402, and second conductive layer 1403 further construct a plurality of additional capacitors C′. The additional capacitors C′ are further connected to the corresponding vertical capacitor cups C1-C4, to increase the capacitance of the vertical capacitor cups C1-C4.

As mentioned above, in the method of forming semiconductor structure according to some embodiments of the disclosure, the openings are formed in the support layers in advance, thus the sacrificial layers in the container can be simultaneously removed by a single etching process with single opening the topmost support layer. As a result, the damage at top of the container can be reduced, and the area along vertical direction of the container can be remained larger, thereby increasing capacitance of the container. Additionally, by reducing the loss of the second support layer 1202 and the third support layer 1203, the mechanical strength of the array structure can be enhanced, and the problem of leakage due to container inclined can be prevented.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A method of forming semiconductor structure, the method comprising:
forming a template layer on a substrate, wherein the template layer sequentially comprises, from bottom to top, a first support layer, a first sacrificial layer, a second support layer, a second sacrificial layer, a third support layer, a third sacrificial layer, and a fourth support layer, wherein the second support layer comprises a first opening, the third support layer comprises a second opening, and the second opening substantially corresponds to the first opening;
forming a plurality of through holes penetrating the template layer to expose the substrate, wherein the through holes partially overlap the first opening and the second opening;
forming a first conductive layer on sidewalls of the through holes and on a top surface of the fourth support layer;
removing a first portion of the first conductive layer and a portion of the fourth support layer in a vertical projection area of the first opening and the second opening to expose the third sacrificial layer;
removing a second portion of the first conductive layer on the fourth support layer;
removing the first sacrificial layer, the second sacrificial layer, and the third sacrificial layer; and
sequentially forming a capacitor dielectric layer and a second conductive layer on the first conductive layer to form a container.

2. The method of claim 1, wherein removing a first portion of the first conductive layer and a portion of the fourth support layer in a vertical projection area of the first opening and the second opening to expose the third sacrificial layer comprises:
forming a patterned photoresist on the first conductive layer, wherein the patterned photoresist, the second support layer, and the third support layer have same distributing pattern; and
patterning the first conductive layer by performing an etching process using the patterned photoresist as a mask.

3. The method of claim 2, wherein a height of the third sacrificial layer within the vertical projection area of the first opening and the second opening is between the fourth support layer and the third support layer, after performing the etching process.

4. The method of claim 2, wherein the template layer comprises a capacitor array area and a preserved area, and the first opening and the second opening are in the capacitor array area.

5. The method of claim 4, wherein the first sacrificial layer, the second sacrificial layer, and the third sacrificial layer within the vertical projection area of the first opening and the second opening are continuous.

6. The method of claim 5, wherein the first sacrificial layer, the second sacrificial layer, and the third sacrificial layer in the preserved area are continuous.

7. The method of claim 6, wherein the first sacrificial layer, the second sacrificial layer, and the third sacrificial layer in the capacitor array area and the preserved area are removed simultaneously by performing a wet etching process.

8. The method of claim 1, further comprising depositing a polysilicon material to fill a spacing in the container, wherein the polysilicon material covers a top surface of the container.

9. The method of claim 1, wherein a shape of each of the first opening and the second opening is an ovular or an ellipse.

10. The method of claim 9, wherein a number of the through holes is four, and the through holes are arranged at long-axis and short axis of the first opening and the second opening.

11. A semiconductor structure, comprising:
a substrate comprising a semiconductor substrate, a dielectric layer disposed on the semiconductor substrate, and a plurality of metal contacts disposed in the dielectric layer; and
a container comprising a plurality of vertical capacitor cups connected to the metal contacts, respectively, wherein each of the vertical capacitor cups has an inner height and an outer height, and the inner height is smaller than the outer height.

12. The semiconductor structure of claim 11, further comprising:
a first support layer, a second support layer, a third support layer, and a fourth support layer disposed sequentially on the substrate, from bottom to top, wherein the inner height is between the third support layer and the fourth support layer.

13. The semiconductor structure of claim 12, wherein the outer height is measured at a side surface of each of the vertical capacitor cups that contacts the second support layer, the third support layer, and the fourth support layer.

14. The semiconductor structure of claim 12, wherein the outer height is higher than the fourth support layer.

15. The semiconductor structure of claim 12, wherein the inner height is measured at a side surface of each of the vertical capacitor cups that is not adjacent the second support layer, the third support layer, and the fourth support layer.

16. The semiconductor structure of claim 12, further comprising a plurality of additional capacitors laterally connected to the vertical capacitor cups.

17. The semiconductor structure of claim 16, wherein the additional capacitors are spaced by the second support layer and the third support layer.

18. The semiconductor structure of claim 12, further comprising:
a polysilicon material filling a spacing between the first support layer, the second support layer, the third support layer, and the fourth support layer, wherein the polysilicon material covers a top surface of the container.

19. The semiconductor structure of claim 12, wherein at a plane of the third support layer, the vertical capacitor cups are complete rings.

20. The semiconductor structure of claim 12, wherein at a plane of the fourth support layer, the vertical capacitor cups are not complete rings.
